(19) United States
(12) Patent Application Publication
(10) Pub. No.: US 2008/0303149 A1
(43) Pub. Date: Dec. 11, 2008

(54) Electronic Component

(75) Inventors: Toshiharu Takayama, Nagano (JP); Ryuusuke Suzuki, Nagano (JP); Takefumi Nakamori, Nagano (JP)

Correspondence Address: HARNESS, DICKEY & PIERCE, P.L.C., P.O. BOX 828, BLOOMFIELD HILLS, MI, 48303, US

(73) Assignee: MINOWA KOA INC., Nagano (JP)

(21) Appl. No.: 10/593,535

(22) PCT Filed: Jan. 21, 2005
(86) PCT No.: PCT/JP2005/000760

§ 371 Date: Aug. 20, 2008

(30) Foreign Application Priority Data
Mar. 24, 2004 (JP) 2004-086573
Jun. 17, 2004 (JP) 2004-179092
Jul. 30, 2004 (JP) 2004-224064

(51) Int. Cl. H01L 23/488

(52) U.S. Cl. 257/738; 257/E23.023

(57) ABSTRACT

An electronic component including, on one surface of a substrate (1), a plurality of circuit elements and external terminals each consisting of a conductive protrusion (9) for the circuit elements is provided with a structure capable of resisting an external force after mounting. Each of the circuit elements includes, as constituent elements, a pair of electrodes (2) and a resistive element (3) or a dielectric contacting with the pair of electrodes (2), each circuit element is covered with an overcoat (7) while the electrodes (2) are partially exposed as lands (4), the conductive protrusion (9) includes a fixedly bonding member, the conductive protrusion (9) is fixedly bonded to each of the lands (4) by the fixedly bonding member, at least three lands (4b) of the lands (4) are larger in area than the other lands (4a), the electronic component can stand alone while the conductive protrusion (9) contacts with a flat if the conductive protrusion (9) is fixedly bonded only to each of the larger-area lands (4b), and the conductive protrusions are all formed by fixedly bonding conductive balls (10) substantially equal in size to entire surfaces of the respective lands (4).

### TECHNICAL FIELD

The present invention relates to an electronic component including a plurality of circuit elements and external terminals for the circuit elements each consisting of a conductive protrusion on one surface of a substrate.

### BACKGROUND ART

An electronic component including a plurality of circuit elements and external terminals for the circuit elements each consisting of a conductive protrusion on one surface of a substrate is disclosed in U.S. Pat. No. 6,326,677 and International Publication No. WO97/30461.

A technique for providing an enlarged land in each corner of a bottom of an IC chip 21 and thereby making the IC chip 21 resist against an external force in a mounted state is disclosed in Japanese Patent Application Laid-Open No. 2003-031728 (FIG. 10).

Patent Literature 1: U.S. Pat. No. 6,326,677

Patent Literature 2: International Publication No. WO97/30461

Patent Literature 3: Japanese Patent Application Laid-Open No. 2003-031728

### DISCLOSURE OF THE INVENTION

### Problems to be Solved by the Invention

However, for the electronic component in which an area of one surface of the substrate is occupied by the plurality of circuit elements and conductive protrusions, it is often inappropriate to simply enlarge the lands so as to only provide a structure that can resist the external force. The reason is as follows. The area of one surface of the substrate of the electronic component is occupied excessively by as much as presence of the conductive protrusions, as compared with an electronic component that does not include the conductive protrusions. Because, it is necessary to secure an area for arranging the circuit elements including predetermined characteristics. This should be taken into particular consideration if a reduction in size of the electronic component is increased.

It is, therefore, necessary for the electronic component in which the area of one surface of the substrate is occupied by the plurality of circuit elements and conductive protrusions to have a structure capable of resisting the external force while giving due consideration to particularity of the structure, arrangement of the circuit elements and the lands on which the conductive protrusions are mounted, an occupation rate of the substrate area, and the like. Examples of the external force include a mechanical stress (shock) and a thermal stress (shock).

It is an object of the present invention to provide an electronic component in which an area of one surface of a substrate is occupied by a plurality of circuit elements and conductive protrusions with a structure that can resist an external force after mounting.

### Means to Solve the Problems

To solve the problems, an electronic component according to the present invention is an electronic component including, on one surface of a substrate 1, a plurality of circuit elements and external terminals for the circuit elements, each of the external terminals consisting of a conductive protrusion 9, characterized in that each of the circuit elements includes, as constituent elements, a pair of electrodes 2 and a resistive element 3 or a dielectric contacting with the pair of electrodes 2, each circuit element is covered with an overcoat 7 while the electrodes 2 are partially exposed as lands 4, the conductive protrusion 9 includes a fixedly bonding member, the conductive protrusion 9 is fixedly bonded to each of the lands 4 by the fixedly bonding member, at least three lands 4b of the lands 4 are larger in area than the other lands 4a, the electronic component can stand alone while the conductive protrusion 9 contacts with a flat if the conductive protrusion 9 is fixedly bonded only to each of the larger-area lands 4b, and the conductive protrusions 9 are all formed by fixedly bonding conductive balls 10 substantially equal in size to entire surfaces of the respective lands 4. The larger-area lands will be referred to as “lands 4b”, the other lands (ordinary or smaller-area lands) will be referred to as “lands 4a”, and the lands 4a and 4b are generically referred to as “lands 4” if it is necessary to do so.

Examples of the “electronic component” include a network resistor (as shown in, for example, FIG. 1) configured so that a plurality of resistive elements are connected to one another by a common electrode 2b, a so-called CR component configured so that a resistive element is connected to a capacitor, and a so-called multiple resistor or multiple capacitor configured so that a plurality of independent resistive elements or capacitors are arranged on one surface of a substrate. In addition, the examples of the “electronic component” include an electronic component configured so that these circuit elements are formed into multilayer circuit elements by a resin layer, a ceramic layer or the like.

Examples of the “substrate 1” include a substrate consisting of ceramic such as alumina, a substrate consisting of an epoxy resin into which glass fiber is mixed, and the like. The ceramic is a suitable material since it is superior in rigidity than the other materials for the following reasons. For the electronic component having a structure in which the circuit elements are directly formed on the substrate 1, a deformation of the substrate 1 due to an external force tends to cause deviation of a resistance and a capacity from their respective rated values. If the ceramic is used as the material for the substrate 1, the deformation can be prevented as much as possible. The knowledge that the substrate 1 preferably has such rigidity and the structure in which the circuit elements are directly arranged on the substrate 1 are not mentioned in the technique for the IC chip 21 (as disclosed in Japanese Patent Application Laid-Open No. 2003-031728). This technique essentially differs in technical concept from the present invention. Further, because of the existence of the conductive protrusion 9, the external force tends to be applied to the conductive protrusion 9. It is, therefore, necessary that the substrate 1 is flexible and the resistance and capacity of each circuit element are changed. In this respect, the surface mount electronic component that does not include the conductive protrusions essentially differs in technical concept from the present invention.

A first reason for “including a plurality of circuit elements and external terminals for the circuit elements, the external terminals each consisting of a conductive protrusion 9 on one surface of a substrate 1” is that this can advantageously facilitate manufacturing the electronic component. Namely, in order to form such members as the circuit elements on both surfaces of the substrate 1, it is of ten necessary to make fine adjustment for positioning to arrange the members on one surface of the substrate and to arrange the members on the other surface of the substrate 1. This adjustment is difficult since it is impossible to view the both surfaces of the substrate 1 simultaneously. It is also necessary to keep the other surface of the substrate 1 clean when the members are arranged on one surface of the substrate 1, and to give due considerations to not damaging the members already arranged on the other surface of the substrate 1. This greatly restricts design of manufacturing steps. In that respect, the configuration of the present invention in which the circuit elements and the conductive protrusions 9 are arranged on one surface of the substrate 1 does not cause or hardly causes such difficulties and restrictions. Normally, some indication is given to the electronic component. However, such an indication is normally considered to be provided on the other surface of the substrate 1 (or a film colored to make the indication conspicuous may be interposed between the indication and the substrate 1). In that case, since no circuit elements is formed on the other surface of the substrate 1, it is advantageously unnecessary to consider an adverse effect (e.g., application of a stress, application of a thermal shock or the like) of execution of an indication step on the circuit elements.

A second reason for “including a plurality of circuit elements and external terminals for the circuit elements, the external terminals each consisting of a conductive protrusion 9 on one surface of a substrate 1” is to clearly distinguish this electronic component from an electronic component in which areas of all lands can be enlarged to some extent such as one including lands arranged on one surface of the substrate 1 and the other circuit element constituent members arranged on the other surface of the substrate 1. As a result of facilitating manufacturing, for the electronic component including the lands and the other circuit element constituent members arranged on one surface of the substrate 1, the area by which the lands 4 can occupy one surface of the substrate 1 is restricted due to the relationship between the lands 4 and the other circuit element constituent members. Such a restriction can contribute to reduction in a region in which the lands 4 are fixedly bonded to the circuit board 12 due to a reduction in the areas of the lands 4. It is, therefore, considered that means for solving the problems according to the present invention are on the premise of a particularly difficult configuration.

Examples of the “conductive protrusion 9” include a conductive ball 10 such as a so-called solder ball 10 mounted and fixedly bonded onto each land 4, a bump formed by a so-called subtraction method or an additive method, and a conductive protrusion obtained by forming a conductive paste into a protrusion by printing or the other method and solidifying the protrusion.

The “overcoat 7” may be a film consisting of resin such as epoxy resin, a glass film, or a film including two or more layers of the resin film and the glass film. The overcoat 7 is to form the lands 4 and to cover up the circuit elements. Considering easiness of patterning when forming a thick film or the like, all regions except for the lands 4 may be covered with the overcoat 7. If each land 4 is formed by an opening of the glass overcoat and an opening of the resin overcoat which is provided over the glass overcoat, it is preferable that the opening of the glass overcoat is smaller in diameter than that of the resin overcoat. With such a configuration, if a solder is used as a fixedly bonding member for fixedly bonding the conductive ball 10 to each land 4, it is the glass overcoat that mainly, directly contacts with the molten solder. If so, glass can prevent the molten solder from entering into a gap between the overcoat and the electrodes that constitute the land 4. If the resin overcoat directly contacts with the molten solder, the molten solder relatively easily enters into the gap between the overcoat and the electrodes that constitute the land 4. This may possibly cause the solder to be moved to a position at which it is difficult for the solder to sufficiently play its original role as the fixedly bonding member.

The expression “fixedly bonding to the land 4” means fixedly bonding mainly using the solder serving as the fixedly bonding member. A surface of the land 4 and the conductive protrusion 9 are required to have good wettability to the solder to some extent. The solder is, therefore, present substantially throughout the lands 4. The conductive protrusion 9 fixedly bonded to the land 4b is fixedly bonded to the land 4b more strongly than the other conductive protrusions 9 for the following reasons. The solder that supports the conductive ball 10 is large in amount, and an area by which the solder that supports the conductive ball 10 from surroundings of the ball 10 is fixedly bonded to the land 4b is larger than an area by which the solder is fixedly bonded to the land 4a.

“At least three lands 4b of the lands 4 are larger in area than the other lands 4a” is to improve the bonding strength of the conductive protrusion 9 and to provide the structure capable of resisting the external force after the electronic component according to the present invention is mounted on the circuit board of an electronic apparatus or the like by the cream solder or the like. It is verified by a test, to be described later, that the area of the land 4b is preferably about 1.4 times as large as the area of the land 4a. Nevertheless, various premises (absolute values of the areas of the lands 4a and 4b, a degree of the external force, and the like) are required to determine whether or not such an area ratio is appropriate. This area ratio is not a constituent requirement of the present invention. Needless to say, this area ratio is preferably lower for pattern designing.

If one electronic component includes many lands 4 and the lands 4 have three or more different areas, then the smallest-area land 4 is assumed as the “land 4a” and the lands 4 having the other two or more areas are assumed as the “lands 4b”.

The reason for setting, as a constituent requirement, the fact that “the electronic component can stand alone while the conductive protrusion 9 contacts with a flat if the conductive protrusion 9 is fixedly bonded only to each of the larger-area lands 4b” is to arrange the strongly, fixedly bonded conductive protrusions 9 in good balance in the mounted state. The meaning of “can stand alone” is that the electronic component can be supported only by contacting the conductive protrusions 9 on the flat without letting the substrate 1 contact with the flat. This good-balanced arrangement can provide the structure that can resist the external force in every direction after mounting. For instance, the areas of the lands 4 located in four corners of the tetragonal substrate 1 are made larger. Whether or not “the electronic component can stand alone” is one index of determining whether the arrangement is in good balance.

By “forming all the conductive protrusions 9 by fixedly bonding conductive balls 10 substantially equal in size to entire surfaces of the respective lands 4”, the conductive ball 10 arranged on each land 4b is supported by the fixedly bonding member in a wider range. As a result, the effect of increasing the bonding strength between the land 4b and the fixedly bonding member if the area by which the ball 10 is fixedly bonded to the land 4b by the fixedly bonding member is larger can be produced. Accordingly, the bonding strength by which the conductive ball 10 is fixedly bonded to the land 4b is intensified and the electronic component that can resist the external force while the electronic component is mounted on the circuit board 12 can be obtained. The problems to be solved by the present invention can be, therefore, solved.

With a view of intensifying the bonding strength by which the conductive ball 10 is fixedly bonded to the land 4b and obtaining the electronic component that can resist the external force while the electronic component is mounted on the circuit board 12, as many lands 4b as possible are preferably provided. However, from viewpoints of ensuring constant circuit element characteristics, it is necessary to consider a balance of the area by which each of or both of the resistive elements and the dielectric as well as the electrodes occupy the substrate 1. It is, therefore, preferable that the number of lands 4b is about ⅓ to ½ of the total number of lands 4 and that an area ratio by which the entire lands 4 occupies the substrate 1 is about 22 to 27%.

In the electronic component according to the present invention or the electronic component having a preferable configuration based on the electronic component according to the present invention, it is preferable that each of the lands 4b is located at a position proximate to an external end of the substrate 1. The external force tends to be applied to the external end of the substrate 1. Due to this, if the bonding strength between the conductive ball 10 and each land 4 on the external end is intensified, it is considered to eventually provide the structure that can better resist the external force.

In the electronic component according to the present invention or the electronic component having a preferable configuration based on the electronic component according to the present invention, it is preferable that the conductive balls 10 are fixedly bonded to the entire surfaces of the respective lands 4 by the fixedly bonding member having an amount generally proportional to an area of each of the lands 4. The expression “generally proportional” refers to the relationship between the amount of the fixedly bonding member and the area of each land 4 if an area of each opening of a screen is made coincident with the area of each land 4 when the fixedly bonding member such as the cream solder is arranged on each land 4 by, for example, an ordinary screen printing technique. Namely, the word “generally” is used to signify that the relationship includes an error corresponding to an irregularity in an emission amount from the screen opening in the ordinary screen printing.

The fixedly bonding member by the amount generally proportional to the area of each land 4 is present on the land 4b by a larger amount than that present on the land 4a. If so, the effect of improving the bonding strength between the fixedly bonding member and the conductive ball 10 is considered to be produced. Besides this effect, the effect of improving the bonding strength between the land 4b and the fixedly bonding member if the area of each land 4 is larger is obtained. It is, therefore, possible to obtain the electronic component that can further resist the external force while the electronic component is mounted on the circuit board 12.

Further, “the conductive balls 10 substantially equal in size” means a diameter of each conductive ball 10 falls within an error range to some extent. The “error range to some extent” means a range of allowing an irregularity in the diameter of the conductive ball 10 which range does not hamper all the conductive balls 10 from being fixedly bonded to the lands 13 of the circuit board when the electronic component is mounted on the circuit board 12. The range is such that [maximum-minimum]/[average] of the diameters of the conductive balls 10 employed in one electronic component is equal to or smaller than about 5% if the conductive balls 10 are, for example, copper balls (except for solder that covers up surfaces of the balls).

It is considered that the other factor for the present invention to be able to solve the problems is that the conductive protrusion 9 arranged on the land 4b is larger in thickness than the conductive protrusion 9 arranged on the land 4a (FIGS. 5 and 6). In addition, a cause that the thickness is larger is deposition of the fixedly bonding member by the amount generally proportional to the area of each land 4 on the conductive ball 10. The “deposition” includes herein that the cream solder 8 serving as the fixedly bonding member for the land 4 covers up a surface of the conductive ball 10 (which surface is covered with, for example, the solder) having a good solder wettability. Accordingly, as will be described later, no special step is required to increase the thickness of the conductive protrusion 9 arranged on each land 4b and the manufacturing process often remains uncomplicated.

According to the conventional technique (Japanese Patent Application Laid-Open No. 2003-031728), a cream solder present on the enlarged land is shown in FIGS. 2 to 4 and FIG. 7 (as shown in FIG. 10 of the present invention). To form a columnar object using the cream solder as shown in FIG. 10, it is considered to be necessary to execute a step that is not clearly described in the specification of the conventional technique or to execute a complicated step. The reasons are as follows. Even if the cream solder is supplied to ordinary lands and enlarged lands by the same method (e.g., screen printing), and the cream solder is molten and solidified, the cream solder cannot be secured by a sufficient amount to form columnar cream solders on each enlarged land as shown in FIG. 10. If the cream solder is supplied to each enlarged land, until the columnar object as shown in FIG. 10 is formed, by the same method (e.g., screen printing) as that for the other ordinary lands, there is probably no avoiding short-circuit with the adjacent ordinary land. This is because the amount of the cream solder is excessive. According to the conventional technique (Japanese Patent Application Laid-Open No. 2003-031728), therefore, a step necessary to make the cream solder supplied to the lands corresponding to the enlarged lands of a circuit board 23 different in amount from the cream solder supplied to the lands corresponding to the other ordinary lands is executed. For instance, a dispenser is employed to make the amount of the cream solder supplied onto each land of the circuit board 23 different.

According to the present invention, by contrast, “the conductive balls 10 substantially equal in size are fixedly bonded to the entire surfaces of the respective lands 4 by the fixedly bonding member having an amount generally proportional to an area of each of the lands 4”. Therefore, first, the conductive balls 10 equal in size can be used to be mounted on the respective land 4 or the like, irrespective of the land 4a or 4b, so that the mounting operation remains uncomplicated. Second, since the fixedly bonding member by the amount generally proportional to the area of each land 4 is used to fixedly bond the conductive ball 10 to each land 4, if the screen printing is used, for example, it suffices to set the area of each opening of the screen to correspond to the size of each land 4 and it is unnecessary to execute a special step of increasing the amount of the cream solder only for the specific land 4b. Third, the problems can be solved by the present invention by setting the area of the larger-area land 4b about 1.4 times as large as that of the land 4a as will be described later. Due to this, the lands 4b can be located not only in the four corners of the substrate 1 but also inward of the lands 4 located on the external ends as shown in FIG. 1. The present invention is different from and advantageous over the conventional technique.

Specifically, for example, the conductive ball 10 the surface of which has excellent solder wettability is mounted on the land 4 on which the cream solder 8 is arranged, and the cream solder 8 is deposited on a side surface of the conductive ball 10 through a reflow step or the like. As a result of this method, the thickness of the solidified cream solder 11 deposited on the side surface of the conductive ball (e.g., the solder ball 10) of the conductive protrusion 9 fixedly bonded onto the land 4a as shown in FIG. 5(a) is smaller than the thickness of the conductive ball 10 deposited on the land 4b (FIG. 5(b)). This difference in thickness results from a difference in the amount of the cream solder.

With this method, it suffices to mount “the conductive balls substantially equal in size” on both the lands 4a and 4b, respectively. Therefore, it is possible to avoid a complicated operation for mounting the conductive balls 10 different in diameter on the surface of the same substrate 1. Further, it is possible to avoid difficulties in mounting the electronic component on an electronic apparatus circuit board or the like since heights of the conductive balls 10 from the surface of the substrate 1 differ in the single electronic component because of mounting the conductive balls 10 having different diameters on the surface of the substrate 1. It is thereby possible to obtain these great advantages.

It is verified by the test to be described later that it is appropriate to set the maximum thickness of the conductive protrusion 9 fixedly bonded to the land 4b about 1.2 times or more as large as the maximum thickness of the conductive protrusion 9 fixedly bonded to the land 4a so as to provide the structure that can resist the external force. However, various premises (an absolute value of the maximum thickness of the conductive protrusion 9, the degree of the external force, and the like) are required to determine an appropriate thickness ratio. This thickness ratio is not, therefore, a constituent requirement of the present invention.

For the electronic component according to the present invention, due consideration is given to particularity of the structure of the electronic component in which the area of one surface of the substrate 1 is occupied by a plurality of circuit elements and the conductive protrusions 9. If the particularity of the structure of the electronic component according to the present invention is further considered, for example, the necessity that the substrate 1 is made flexible in response to the external force and that such characteristic values of each circuit element as the resistance are changed, it is preferable that the substrate 1 is a high rigidity ceramic substrate 1 as already described.

In the electronic component according to the present invention or the electronic component having a preferable configuration based on the electronic component according to the present invention, it is preferable that the “land 4b” is one of a tetragon, an ellipse, and a tetragon having four round corners (hereinafter, “tetragon and the like”), and/or that a size of the substrate 1 in a direction of a longer side of the substrate 1 is larger than a size of the substrate 1 in a direction of a shorter side of the substrate 1 on each land 4b (FIGS. 2(a) and 2(b)). The reason that the shape is one of the tetragon and the like is that the area of the land 4 can be made large. If the area of the land 4 is larger, it is possible to secure the fixedly bonding member such as the cream solder 8 or the epoxy conductive adhesive provided on the land 4 and having the amount generally proportional to the area of the land 4 sufficiently to fixedly bond the conductive protrusion member 9 to the land 4. If the amount of the fixedly bonding member is sufficient, the structure that can resist the external force after mounting can be provided.

Meanwhile, the reason that the area of the land 4 can be made larger by setting the shape of the land 4 to one of the tetragon and the like is that the region of the land 4 can be secured outside the outline of the conventional circular land 4. Namely, as a square having a side equal in size to a diameter of the circular land 4 has an area 4/π times as large as the area of the circular land, the large area of the land 4 can be secured.

Accordingly, in the electronic component in which the area of one surface of the substrate 1 is occupied by the plural circuit elements and the conductive protrusions 9, by setting shapes of all of or most of (the majority of) the lands 4 to one of the tetragon and the like, it is possible to increase the occupation rate of the area of the lands 4 on the surface of the substrate 1 without providing the “lands 4b”. It is, therefore, possible to intensify the bonding strength of the electronic component while the electronic component is mounted on the circuit board 12 and provide the electronic component that can resist the external force.

Furthermore, the reason that it is preferable that the size of the substrate 1 in the direction of the longer side of the substrate 1 is larger than that in the direction of the shorter side of the substrate on each of all the lands 4 of the electronic component in which the area of one surface of the substrate 1 is occupied by the circuit elements and the conductive protrusions 9 as shown in, for example, FIG. 2, as compared with the conventional lands 4 that are normally circular is as follows. The fixedly bonding member reinforces the substrate 1 along the direction of the longer side of the substrate 1. The substrate 1 is normally deformed along the longer side direction when the external force is applied thereto. The reinforcement by the fixedly bonding member functions to suppress the deformation of the substrate 1. The electronic component according to the present invention, therefore, has the structure that can resist the external force after mounting and can solve the problems to be solved by the present invention. This function can be obtained even if the size of the substrate 1 in the direction of the longer side of the substrate 1 is set larger than the size of the substrate 1 in the direction of the shorter side of the substrate 1 on one of or each of the lands 4b and 4a.

Moreover, even for the electronic component in which, for example, the area of one surface of the substrate 1 is occupied by the plural circuit elements and conductive protrusions 9, it is unnecessary to change the magnitude of the resistive element 3 or the dielectric from that according to the conventional technique. The characteristics of each circuit element are not deteriorated accordingly.

Examples of the “tetragon” among the tetragon and the like include a rectangle, a square, a rhomb, trapezoid, and shapes slightly deformed therefrom.

If the electronic component according to the present invention or the electronic component having a preferable configuration based on the electronic component according to the present invention is a resistor, it is more preferable that the resistive element 3 is formed on the substrate 1, the electrode 2 is directly formed on the resistive element 3, and the electrode 2 constitutes the land 4b. This is because the land 4 can be formed even in the electrode 2 region in which the resistive element 3 and the electrode 2 are superimposed and the larger area of the land 4b can be secured. With the conventionally adopted configuration in which the electrode 2 is formed on the substrate 1 and in which the resistive element 3 is directly formed on the electrode 2, it is impossible or quite difficult to form the land 4 in the electrode 2 region in which the resistive element 3 and the resistive element 2 are superimposed.

If the electronic component according to the present invention or the electronic component having a preferable configuration based on the electronic component according to the present invention is the resistor, it is preferable that the region in which the electrode 2 extending from the land 4b is connected to the resistive element 3 while superimposing each other is present while avoiding a line that connects a shortest path between a center of the land 4 and the electrode 2 that pairs with the electrode and that is provided on the other end. This is because a distance in a current direction can be secured in the region in which the electrode 2 and the resistive element 3 are superimposed each other. If this distance is not equal to or larger than a certain distance, a problem in relation to maintaining the characteristics of the resistive element such as a change in the resistance resulting from generation of an excessive Joule's heat occurs when an excessive voltage is applied between terminals of the resistive element. However, by increasing areas of part of lands, there is possibly no avoiding reducing the area by which the electrode 2 extending from the land 4b is superimposed with the resistive element 3 or the distance only for a specific resistive element. By forming the region in which the electrode 2 and the resistive element 3 are superimposed each other while avoiding the line, the distance can be sufficiently secured (FIGS. 1 and 2). If the distance cannot be secured sufficiently, an excessive Joule's heat is generated in the portion in which the electrode 2 and the resistive element 3 are superimposed each other, which often adversely influences the temperature characteristic (e.g., TCR) of the resistive element.

To secure the distance in the current direction in the region in which the electrode 2 and the resistive element 3 are super imposed each other, a position of an end of the resistive element 3 in the current direction is made present while avoiding the line that connects to the shortest path between the center of the land 4 and the electrode 2 that pairs with the electrode and that is provided on the other end. By doing so, even if the resistive element 3 is arranged on the line, the resistive element 3 can be advantageously arranged even at a position at which a part of the resistive element 3 is superimposed with the land 4b (see, for example, the positional relationship between the land 4b and the resistive element 3 in FIGS. 1(b) and 2(b)).

In another word, in the electronic component according to the present invention or the electronic component having a preferable configuration based on the electronic component according to the present invention, it is more preferable that a distance between the resistive elements 3 of the resistor that includes the conductive protrusions 9 arranged on the paired lands 4 including the land 4b as the external terminals, respectively, in the current forward direction is larger than the shortest distance between the paired lands 4. This configuration includes an instance in which both of the paired lands 4 are the lands 4b and an instance in which one of the paired lands 4 is formed on the common electrode 2b.

Normally, even if the electronic component is reduced in size, the area of the land 4 is not always reduced at a reduction rate equal to or higher than the reduction rate of the electronic component. This is because it is required that the bonding strength between the electronic component and the circuit board 12 is equal to or higher than a certain value. The preferred configuration is, therefore, more advantageous if the electronic component is made smaller in size.

In the resistor having the above-stated preferred configuration, it is possible to maintain a wide distance between the region in which the paired electrodes 2 are superimposed on the resistor 3, and arrange the lands 4b in good balance. Therefore, the resistor in which the area of one surface of the ceramic substrate 1 is occupied by the plural resistive elements and conductive protrusions 9 can be provided with the structure that can resist the external force after mounting while maintaining predetermined characteristics of the resistive elements. It is considered that the region of the substrate 1 for isolating the adjacent resistive elements from each other on one surface of the substrate 1 is conventionally, excessively provided. However, the above-stated preferred configuration makes it possible to effective use the region.

It is preferable that each land 4b is located at a position proximate to each shorter-side external end of the rectangular substrate 1. After the electronic component according to the present invention is mounted on the circuit board (mounting substrate) 12, if a thermal shock is repeatedly applied to the electronic component thus mounted thereon, a difference in coefficient of thermal expansion and coefficient of thermal contraction between the circuit board 12 and the substrate 1 is transformed into “external force”. The external force often deviates relative positions of the land of the substrate 1 at the beginning of mounting and a land 13 of the circuit board 12 (a portion of the circuit board 12 to which the conductive protrusion 9 of the electronic component is fixedly bonded). This relative positional deviation is generated uniformly throughout the substrate 1 and the circuit board 12. As a result, the deviation is conspicuous at a position away from a central position of the substrate 1. Accordingly, if the substrate 1 is rectangular, both ends of the substrate 1 in the longer side direction (positions proximate to the both ends of the substrate 1 in the shorter side direction) are regions in which the positional deviations are conspicuously generated. Considering this, by setting the area of each land 4 on one surface of the substrate 1 large so as to strongly, fixedly bond these regions to the circuit board 12, it is possible to provide the electronic component with the structure that can resist the “external force”, if any, most appropriately. Besides, since it is not required to set the areas of the other lands 4 large, it is possible to maintain predetermined characteristics of each circuit element.

In the electronic component according to the present invention or the electronic component having a preferred configuration based on the electronic component according to the present invention, it is preferable that each land 4b includes conductive ball 10 holding means. If the area of each land 4 is made larger, there is a probability that a position at which the conductive ball 10 arranged on the land 4 is fixedly bonded to the land 4 is deviated. If the land 4b is tetragonal, in particular, it is often difficult to expect an effect of correcting the position of the conductive ball 10 resulting from the surface tension of the molten solder when the solder is used as the fixedly bonding member for fixedly bonding the conductive ball 10 to each land 4b, as compared with a circular ball. A specific example of the conductive ball 10 holding means is means for arranging in advance a protruding member that can hold the ball 10 on one surface of the substrate 1 under a conductive film that constitutes the land 4b and that consists of a Metal Graze® material or the like. Such means advantageously enables the protruding member 14 to be present to raise the conductive film and to hold the ball 10 on the conductive film after formation of the conductive film. The protruding member 14 is arranged on one surface of the substrate 1 by screen-printing a paste such as glass or resin (FIG. 9).

The present invention is effective particularly if the conductive protrusion 9 substantially does not contain lead. Normally, the lead-containing conductive protrusion 9 (which mainly consists of a low melting point alloy such as solder) is lower in rigidity than the conductive protrusion 9 that substantially does not contain lead, and functions as a buffer against the external force. Due to this, deterioration in the state in which the conductive protrusion 9 is fixedly bonded to the land 4 by the external force is small. However, the conductive protrusion 9 that does not contain lead is inferior in function as the buffer, so that it is largely affected by the external force. Further, from viewpoints of environment-friendliness, it is unfavorable that the electronic component contains lead. Preferably, therefore, the conductive protrusion 9 mainly consists of a low melting point metal that does not contain lead, e.g., one or more metals selected from among an Sn, an Sn—Bi alloy, an Sn—In—Ag alloy, an Sn—Bi—Zn alloy, an Sn—Zn alloy, an Sn—Ag—Bi alloy, an Sn—Bi—Ag—Cu alloy, an Sn—Ag—Cu alloy, an Sn—Ag—In alloy, an Sn—Ag—Cu—Sb alloy, an Sn—Ag alloy, an Sn—Cu alloy, and an Sn—Sb alloy. The same thing is true for both the cream solder 8 and the conductive ball 10.

In the electronic component according to the present invention or the electronic component having a preferred configuration based on the electronic component according to the present invention, it is preferable that all the resistive elements 3 that constitute the electronic component are substantially equal in shape, and distances between the adjacent resistive elements 3 are substantially equal. If a current is applied to the resistor, the Joule's heat is always generated in each resistive element 3. If the Joule's heat is so low as to hardly influence the characteristics (e.g., temperature characteristics of resistance (TCR) and the like) of the resistor, no problem occurs. However, if the Joule's heat that influences the TCR is generated and a local thermal concentration occurs depending on the arrangement of the resistive elements 3 of the electronic component, a difference in characteristics among the respective resistor is often conspicuous. If that resistive elements 3 that constitute the electronic component are substantially equal in shape, and distances between the adjacent resistive elements 3 are substantially equal, it is effective to prevent such a local thermal concentration. By arranging the electrodes 2 and the resistive elements 3 as shown in, for example, FIG. 1(b), the thermal concentration can be prevented.

From these viewpoints or the like, it is more preferable that the conductive protrusion 9 mainly consists of copper. The copper is quite high in coefficient of thermal conductivity as compared with the solder or the like, and can promptly release the Joule's heat generated by the resistor to the mounting circuit board 12. Therefore, even if the resistive elements 3 are arranged so that the local concentration of the Joule's heat may possibly occur, it is possible to stabilize the characteristics of the resistor.

The coefficient of thermal expansion of the copper is about two-thirds of that of the conventionally used solder (consisting of, for example, 37Pb-63Sn alloy). Accordingly, even if the conductive protrusion 9 is fixedly bonded to each land 4 of the substrate 1 and then exposed to an environment in which heating and cooling are repeated, the probability that the conductive protrusion 9 is peeled off from the land 4 is low. Besides, the copper is quite hard as compared with the solder. Due to this, the conductive protrusion 9 made of copper is hardly deformed by handling if the conductive protrusion 9 is formed as the ball 10. It is advantageously possible to keep heights of many conductive protrusions 9 from one surface of the substrate 1 constant.

It is further preferable that a conductive covering layer plated with Ni, Sn or the like is formed on a surface of the copper. This is intended to improve the solder wettability and the like of the conductive protrusion 9 and to prevent oxidation of the surface of the copper. If the copper surface is oxidized, then it is difficult to alloy the conductive protrusion with the solder when the electronic component is mounted on the mounting circuit board, and to obtain a state in which the conductive protrusion 9 is appropriately, fixedly bonded to the mounting circuit board or the land 4.

Examples of the conductive protrusion 9 that mainly consists of the copper include an alloy that mainly consists of pure copper or copper, and a conductive protrusion obtained by forming a solder layer consisting of Sn, an Sn alloy or the like on a surface of the alloy that mainly consists of the pure copper or the copper by plating or the like.

Alternatively, gold can be used in place of the copper. Advantages of use of gold are as follows. It is not always necessary to form the antioxidant layer on the surface of the gold. The gold exhibits a flexibility equal to or higher than the solder. The gold is, therefore, low in rigidity and functions as a buffer against the external force. As a result, deterioration in the state in which the conductive protrusion 9 is fixedly bonded to the land 4 by the external force is small.

In the electronic component according to the present invention or the electronic component having a preferred configuration based on the electronic component according to the present invention, it is preferable that each larger-area land 4b consists of Metal Graze® material, and that an entire surface of each larger-area land 4b is covered with the fixedly bonding member (FIG. 5(b)). The Metal Graze® material is strongly, fixedly bonded to the surface of the ceramic substrate 1 consisting of alumina or the like. This bonding strength is normally higher than that of a copper foil formed on (fixedly bonded onto) the surface of the substrate that consists of epoxy resin into which glass fiber is mixed. The difference in bonding strength therebetween is particularly greater if a temperature of a surrounding environment is higher. This is because the Metal Graze® material and the ceramics are high in heat resistance. In addition, since the fixedly bonding member is provided on the entire surface of each land 4b, the bonding strength for fixedly bonding the conductive protrusion 9 to each land 4b is secured. Accordingly, even if the external force is applied to the conductive protrusion 9 while the conductive protrusion 9 is fixedly bonded to the land 4b, it is possible to effectively suppress the conductive protrusion 9 from being peeled off on an interface between the substrate 1 and the land 4b. Needless to say, it is more preferable that not only the land 4b but also the land 4a consist of the Metal Graze® material and that the entire surface of each land 4a is covered with the fixedly bonding member. Since the land 4b is larger in area than the land 4a, the effect of intensifying the bonding strength by covering the entire surface of the land 4b with the fixedly bonding member is greater.

Alternatively, the Metal Graze® can be replaced by a conductive adhesive. This is because the conductive adhesive that mainly consists of, for example, epoxy resin or acrylic resin can be strongly, fixedly bonded to the surface of the substrate 1 that consists of ceramics such as alumina, similarly to the Metal Graze® material.

### EFFECTS OF THE INVENTION

According to the present invention, it is possible to provide the electronic component in which the area of one surface of the substrate 1 is occupied by a plurality of circuit elements and the conductive protrusions 9 with the structure that can resist the external force after mounting.

### BRIEF DESCRIPTION OF THE DRAWINGS

FIG. 1 shows a positional relationship among electrodes, resistors, and lands of a network resistor according to the present invention, wherein lands 4a and 4b show outlines of regions to be processed into the lands after later steps.

FIG. 2 shows a positional relationship among electrodes, resistors, and lands of another network resistor according to the present invention, wherein lands 4a and 4b show outlines of regions to be processed into the lands after later steps.

FIG. 3 shows steps of manufacturing the network resistor according to the present invention.

FIG. 4 shows steps of manufacturing another network resistor according to the present invention.

FIG. 5(a) is a schematic longitudinal sectional view of an ordinary land in the network resistor according to the present invention, and FIG. 5(b) is a schematic longitudinal sectional view of a larger-area land in the network resistor according to the present invention.

FIG. 6(a) is a schematic longitudinal sectional view of the ordinary land and a conductive protrusion in the network resistor according to the present invention, and FIG. 6(b) is a schematic longitudinal sectional view of the larger-area land and the conductive protrusion in the network resistor according to the present invention.

FIG. 7(a) is a schematic longitudinal sectional view of the ordinary land in the network resistor according to the present invention, FIG. 7(b) is a schematic longitudinal sectional view of the larger-area land in the network resistor according to the present invention, FIG. 7(c) is a schematic longitudinal sectional view of the ordinary land and the conductive protrusion in the case where the network resistor according to the present invention is mounted on a circuit board, and FIG. 7(d) is a schematic longitudinal sectional view of the larger-area land and the conductive protrusion in the case where the network resistor according to the present invention is mounted on a circuit board.

FIG. 8(a) is a schematic view of a side surface state of a longer side of a substrate before a thermal shock application test is conducted to the network resistor according to the present invention, FIG. 8(b) is a schematic view of a side surface state of the longer side of the substrate during cooling in the thermal shock application test, and FIG. 8(a) is a schematic view of a side surface state of the longer side of the substrate during heating in the thermal shock application test.

FIG. 9 shows a state in which apart of the land 4b according to the present invention is raised to hold a conductive ball.

FIG. 10 is a schematic view of a state in which a conventional IC chip is mounted on a circuit board.

### DESCRIPTION OF REFERENCE SYMBOLS

1. Substrate
2. Electrode
2a. Individual electrode
2b. Common electrode
3. Resistive element
4. Land
4a. Ordinary land
4b. Larger-area land
5. Glass
6. Trimming groove
7. Overcoat
8. Cream solder
9. Conductive protrusion
10. Ball
11. Solidified cream solder
12. Circuit board
13. Circuit board land
14. Protruding member
21. IC chip
22. Solidified cream solder
23. Circuit board

### BEST MODE FOR CARRYING OUT THE INVENTION

(Manufacturing of First Network Resistor According to the Present Invention)

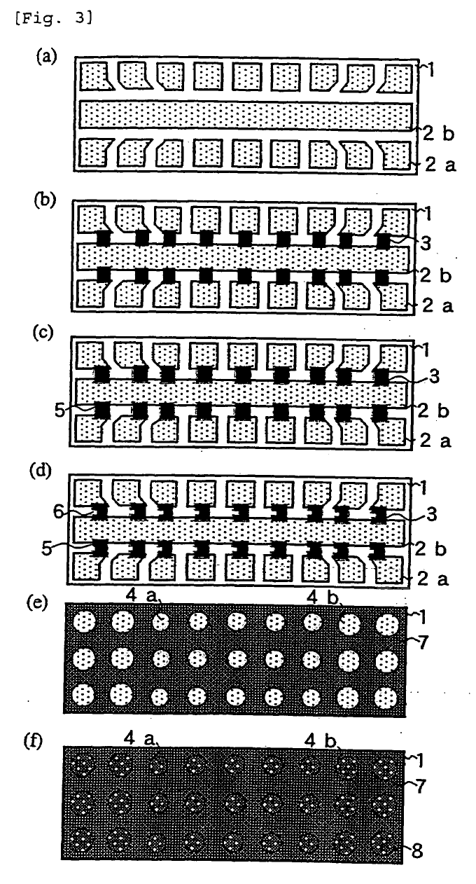

A large-sized substrate 1 consisting of alumina ceramic is prepared. Grooves for division (“division grooves”) are provided both lengthwise and crosswise on both surfaces of the large-sized substrate 1. A minimum unit substrate 1 after the division constitutes one network resistor. A process of forming many resistive elements on one surface of the large-sized substrate 1 having those grooves will now be described with reference to FIG. 3. FIG. 3 illustrates the minimum unit substrate 1 (corresponding to FIG. 1(a)).

First, a Metal Glaze® Ag—Pd containing conductive paste is screen-printed on the substrate 1 shown in FIG. 3(a). Thereafter, the resultant substrate 1 is sintered, whereby individual electrodes 2a and a common electrode 2b a part of which serves as lands for terminal connection of resistive elements are obtained (FIG. 3(a)). As shown in FIG. 3(a), the two individual electrodes 1a from left and right ends from which lands 4b are later formed are formed into a pattern so that resistive elements 3 can be present while avoiding a line that connects a shortest path between each of the individual electrodes 2a and the common electrode 2b that is arranged on the other end and that pairs with the individual electrode 2a.

Next, the common electrode 2b and each individual electrode 2a are set as a pair of electrodes 2, and a Metal Graze® resistive element paste mainly consisting of ruthenium oxide and glass frit is screen-printed on the substrate 1 so as to contact the paired electrodes 2. Thereafter, the resultant substrate 1 is sintered, thereby obtaining the resistive elements 3 (FIG. 3(b)). The resistive elements are thus obtained. A glass paste is then screen-printed on the substrate 1 to cover up the resistive elements 3, and the resultant substrate 1 is sintered, thereby obtaining glasses 5 (FIG. 3(c)). As shown in FIG. 3(c), the resistive element 3 formed between each individual electrode 2a from which the land 4b is later formed and the common electrode 2b that is arranged on the other end and that pairs with the individual electrode 2a is formed to avoid the line that connects the shortest path between those electrodes 2.

Next, to set a resistance of each resistive element to a desired value, a step of forming a trimming groove 6 in the resistive element 3 by irradiation of a laser beam, thereby adjusting the resistance of the resistive element 3 is executed (FIG. 3(d)). At this time, the glass 5 functions to minimize damage of the entire resistive element 3.

Next, to protect the entire resistive element using an overcoat 7, an epoxy resin paste is screen-printed on the substrate 1 and the paste is then heated and solidified (FIG. 3(e)). In providing the overcoat 7, parts of the individual electrodes 2a and the common electrode 2b that are necessary for forming lands 4 are exposed. The lands 4 are formed so that each of the lands 4b on the individual electrodes 2a and the common electrode 2b located at the first and second positions from the left and right ends of the substrate 1 is about 1.4 times as large as a land 4a. If conductive protrusions 9 are fixedly bonded only onto the respective lands 4b, the network resistors can stand alone while the conductive protrusions 9 contact with the flat.

A commercially available cream solder 8 consisting of an Sn—Ag—Cu alloy is arranged on these lands 4 using a metal mask that includes openings substantially corresponding to areas of the respective lands 4 by screen printing (FIG. 3(f)). At this time, the cream solder 8 is formed so as to spread throughout the respective lands 4, whereby the cream solder 8 serving as a fixedly bonding member is supplied to the respective lands 4 by amounts proportional to the areas of the respective lands 4.

Using a commercially available ball 10 mounting device, commercially available pure copper balls 10 (each having a surface plated with Sn) that serve as conductive balls 10 are mounted on the cream solder 8 parts.

Thereafter, a so-called reflow step of holding the substrate 1 as well as the resistive elements and the pure copper balls 10 for a predetermined time at a temperature at which the cream solder 8 is molten and solidified is executed, thereby fixedly bonding and connecting the lands 4 to the respective pure copper balls 10. At this time, a part of each pure copper ball 10 is molten and resolidified together with the cream solder 8, thereby obtaining the “conductive protrusion 9” mainly consisting of pure copper. Further, the pure copper balls 10 are moved to central portions of the respective lands 4 while the cream solder 8 is being molten. This is done by a surface tension of the molten cream solder 8.

Through these steps, the electronic component according to the present invention can be obtained. Thereafter, a stress is applied along the division grooves provided in the substrate 1 and the substrate 1 is divided, whereby each first network resistor according to the present invention can be obtained.

(Manufacturing of Second Network Resistor According to the Present Invention)

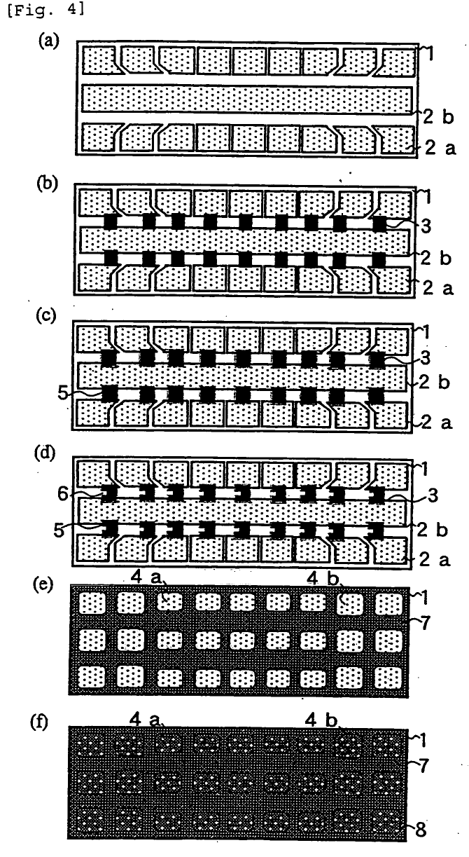

A second network resistor is an example of the electronic component according to the present invention characterized in that the land 4b is a tetragon or the like and/or in that a size of the substrate 1 in a direction of a longer side is larger than a size thereof in a direction of a shorter side on the land 4b. Therefore, the second network resistor is manufactured substantially similarly to the first network resistor according to the present invention in order of steps (a) to (f) shown in FIG. 4. The differences or additions from or to the manufacturing of the first network resistor according to the present invention are as follows. In FIG. 4(a), an individual electrode film 2a in the direction of the longer side of the substrate 1 is set larger in size than that in the direction of the shorter side of the substrate 1. In FIG. 4(e), a shape of each land 4 exposed when the overcoat 7 is provided is a rectangle having round corners.

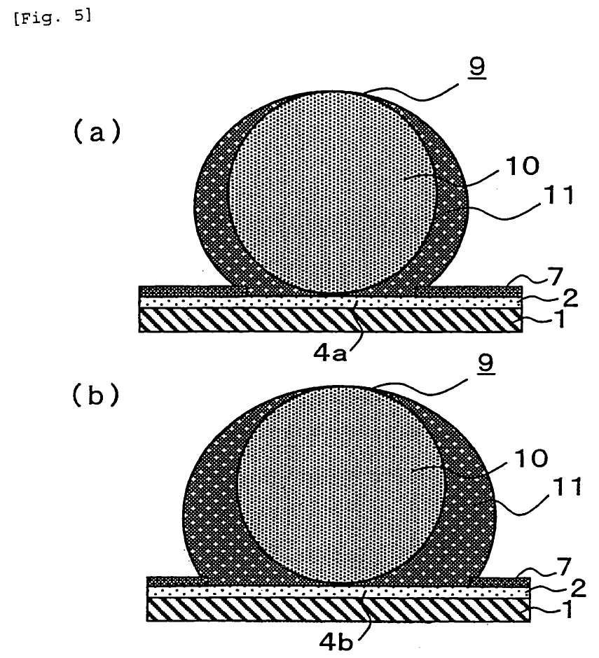

The lands 4 of the first and second network resistors thus obtained are observed. FIGS. 5(a) and 7(a) show a state in which the land 4a is fixedly bonded to the conductive ball 10. FIGS. 5(b) and 7(b) show a state in which the land 4b is fixedly bonded to the conductive ball 10. FIGS. 5(a) and 5(b) show a state in which the cream solder is bonded to substantially entirety of the conductive ball 10 (the solder is wet). FIGS. 7(a) and 7(b) show a state in which the cream solder is bonded only to neighborhoods of the land 4. In the manufactured network resistors, the state shown in FIGS. 5(a) and 5(b) and that shown in FIGS. 7(a) and 7(b) are both recognized.

As evident from FIGS. 5(a), 5(b), 7(a), and 7(b), the solidified cream solder 11 fixedly bonded to the land 4b is larger in amount than that fixedly bonded to the land 4a. In addition, an area by which the solidified cream solder 11 that supports the pure copper ball 10 from surroundings is fixedly bonded to the land 4b is larger than that by which the solidified cream solder 11 is fixedly bonded to the land 4a. The ball 10 arranged on the land 4b is supported by a large amount of the fixedly bonding member in a wider range than that arranged on the land 4b. Further, as evident from FIGS. 5(a) and 5(b), the conductive protrusion 9 fixedly bonded to the land 4b has a largest thickness about 1.2 times as large as that of the conductive protrusion 9 fixedly bonded to the land 4a.

The following respect is substantially common to FIGS. 5(a) and 5(b) and FIGS. 7(a) and 7(b). A bonding strength by which the ball 10 is fixedly bonded to the land 4b is improved by about 40% from that by which the ball 10 is fixedly bonded to the land 4a. To measure the bonding strength, a single ball 10 is fixedly bonded to the land 4 by the same method as that stated above, and a stress is applied to a side surface of the ball 10 along the surface of the substrate 1 in that fixedly bonded state until the ball 10 is peeled off from the land 4. The stress thus applied is measured. The bonding stress is substantially equal between FIGS. 5(a) and 5(b) and FIGS. 7(a) and 7(b). It is, therefore, possible to estimate that a large factor for determining the bonding strength is not the thickness of the conductive protrusion 9 but an area by which the conductive ball 10 is fixedly bonded to the land 4.

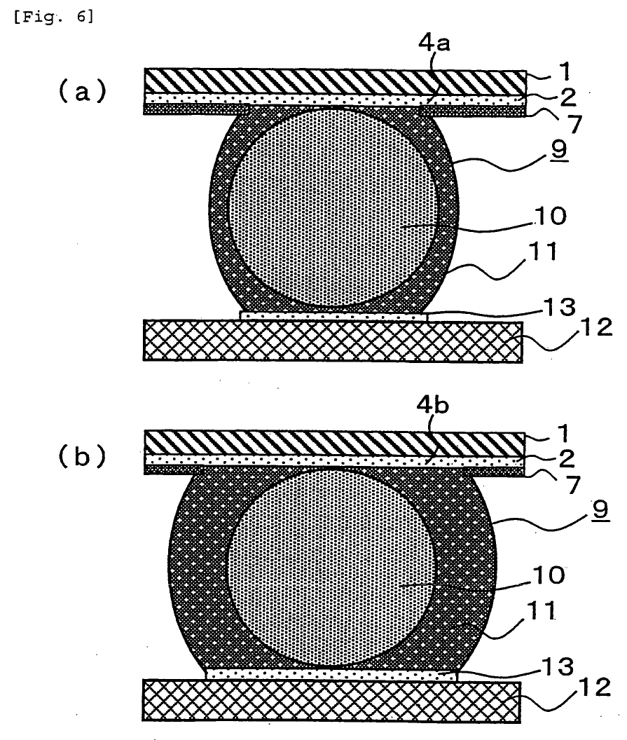

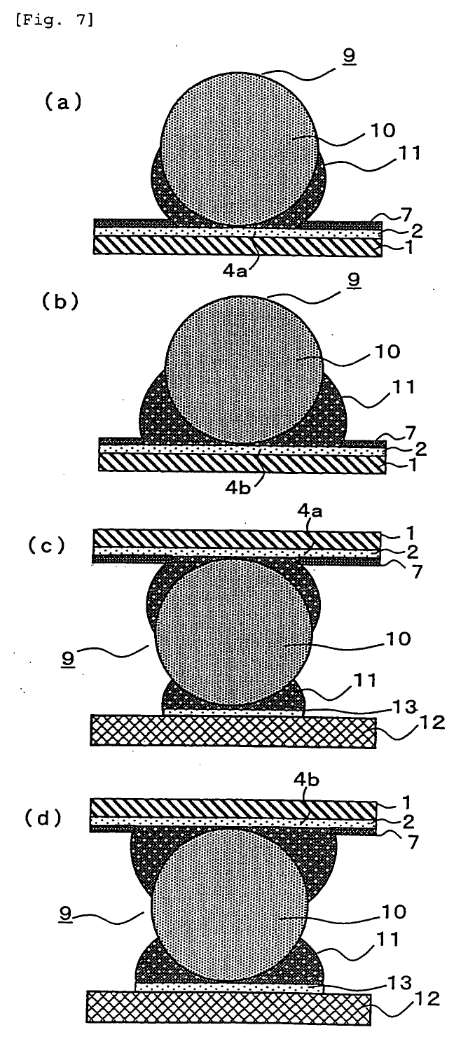

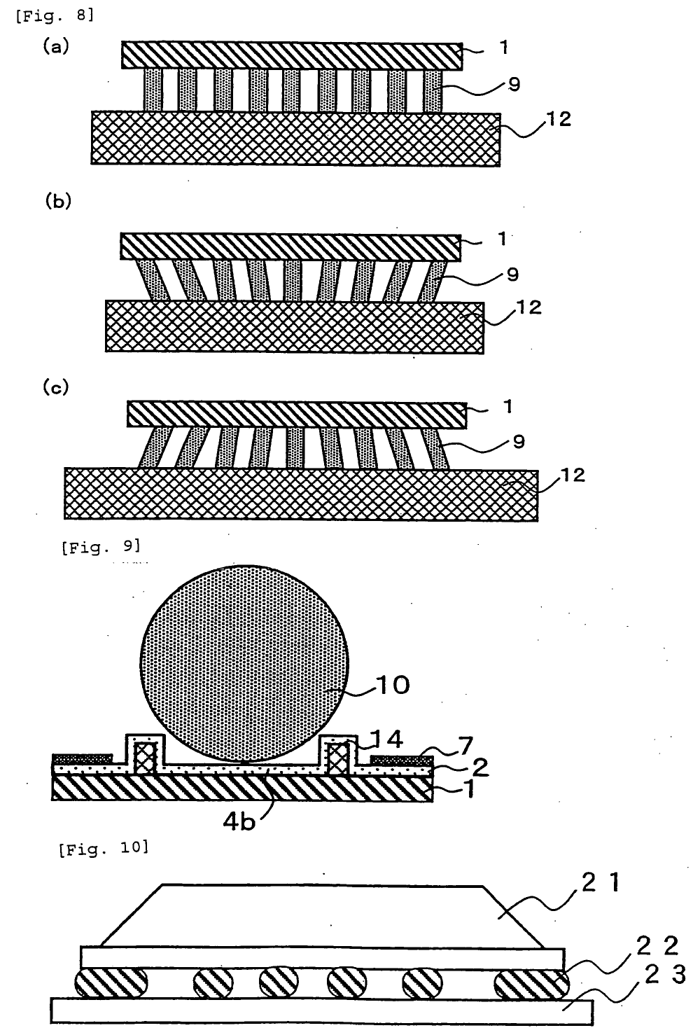

Furthermore, each of the first and second network resistors is surface-mounted on a circuit board (mounting substrate) 12 that is a member consisting of an epoxy resin into which glass fiber is mixed. In mounting, the same cream solder as the above-stated cream solder is screen-printed on a land 13 of the circuit board, and the conductive protrusion 9 of each of the first and second network resistors is arranged on a position of the land 13 of the circuit board. Thereafter, a reflow step is executed similarly to the above. As a result, amounted state shown in FIG. 6 or FIGS. 7(c) and 7(d) is obtained. Thereafter, a test for repeatedly applying the thermal shock to the mounted member in the mounted state is conducted (according to JIS C 5201-1 and the number of times of repeatedly applying the thermal shock is 2000). As a result, the above-stated “external force” resulting from a displacement between the both ends in the longer side direction (positions proximate to both shorter-side external ends of the ceramic substrate 1) is generated. This external force derives from the fact that the circuit board 12 is slightly expanded (FIG. 8(c)) or contracted (FIG. 8(b)) by heating and cooling as shown in FIG. 8. It is understood that the two conductive protrusions 9 at the positions proximate to the respective external ends in FIGS. 8(b) and 8(c) have larger deformations since a greater external force is applied thereto than that applied to the other conductive protrusions 9.

As a result of the test, each network resistor according to the present invention has no apparent change in the state in which the conductive protrusion 9 is fixedly bonded to each land 4 and no change in bonding strength. On the other hand, the network resistor that includes all the lands 4 formed to have ordinary areas (lands 4a) and that is not according to the present invention has a slight apparent change in the state in which the conductive protrusion 9 is fixedly bonded to each land 4. In addition, the conductive protrusion 9 is peeled off from the land 4a at the position corresponding to the position at which the land 4b shown in FIG. 1(a) is arranged. This is considered to be due to the application of a larger stress to the portion in which the conductive protrusion 9 is fixedly bonded to each land 4a, as closer to each external end of the substrate 1 in the longer side direction.

To manufacture each of the first and second network resistors, the sintered Metal Graze® material is used as the material for the land 4. Needless to say, the other material can be used for the land 4. For instance, a patterned copper-foil material, conductive adhesive or the like provided on a surface of the circuit board 12 can be used as the material for the land 4. However, the present invention is particularly advantageous if the Metal Graze® material or the conductive adhesive is used as the material for the land 4 and the solder is used as the fixedly bonding member for bonding the conductive ball 10 to the land 4. The reason is as follows. The Metal Graze® material or the conductive adhesive is normally inferior in solder wettability and is, therefore, lower in bonding strength than the other materials for the land 4. Accordingly, the function of increasing the bonding strength of the land 4 exhibits a greater contribution. If the conductive ball 10 is bonded onto the surface of the Metal Graze® material or the conductive adhesive that is the material for the land 4 using the fixedly bonding member consisting of the solder without solder plating, the solder wettability is further deteriorated. The function of increasing the bonding strength of the land 4 exhibits a further greater contribution.

Moreover, to manufacture each of the first and second network resistors, the pure copper ball is used as the ball 10. Alternatively, a solder ball consisting of Sn-3Ag-0.5Cu or a solder ball different in composition from the former solder ball can be used as the ball 10. Further, a so-called resin core ball can be used as the ball 10.

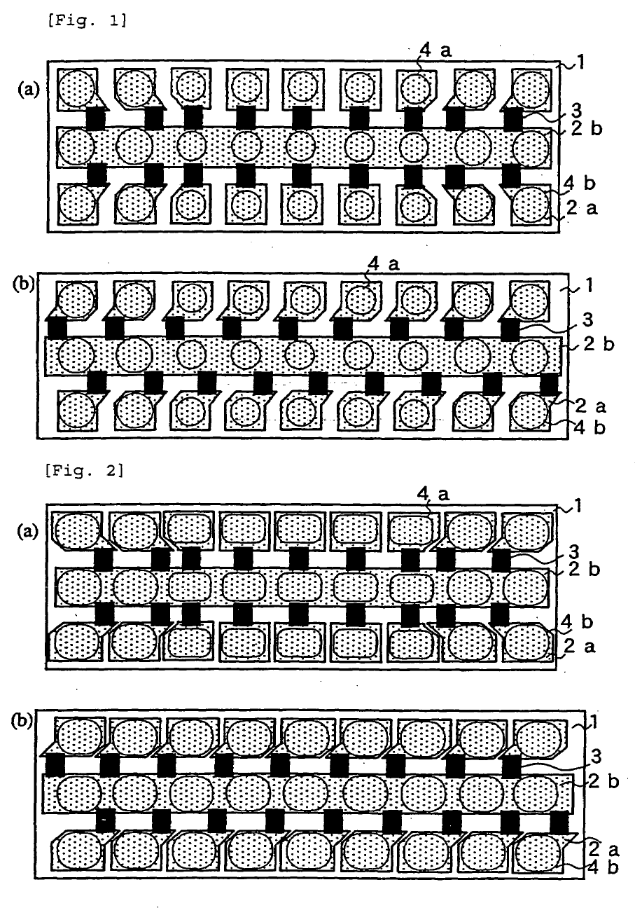

Needless to say, the steps of manufacturing the first and second network resistors shown in FIGS. 3 and 4 can be similarly applied to the network resistors shown in FIGS. 1(b) and 2(b). An advantage of the network resistors by arranging the respective elements as shown in FIGS. 1(b) and 2(b) is prevention of thermal concentration as stated above. On the other hand, a first advantage of the network resistors by arranging the respective elements as shown in FIGS. 1(a) and 2(a) is that external size of each resistor can be slightly reduced as compared with that of each resistor shown in FIGS. 1(b) and 2(b). A second advantage is that the shape of the individual electrode 2b from which each land 4a that does not have a large area is formed can be simplified. Thanks to these, if the electrodes 2b are formed into thick films by screen printing or the like, it is possible to advantageously reduce irregularities in shapes of the electrodes 2b. This is more advantageous if the electronic component is made smaller in size.

The division grooves are formed on the both surfaces of the substrate 1. However, it often suffices to form the grooves only on one surface. It is difficult to align the grooves on the both surfaces particularly if the grooves are formed by laser scribing. In this case, it is rather preferable to form the grooves only on one surface of the substrate 1.

### INDUSTRIAL APPLICABILITY

The present invention can be applied in electronic component-related industries for the network resistor including, on one surface of the substrate, a plurality of circuit elements and the external terminals each consisting of the conductive protrusion for the circuit elements and the like.

1. An electronic component including, on one surface of a substrate, a plurality of circuit elements and external terminals for the circuit elements, each of the external terminals consisting of a conductive protrusion, wherein
each of the circuit elements includes, as constituent elements, a pair of electrodes and a resistive element or a dielectric contacting with the pair of electrodes, said each circuit element is covered with an overcoat while the electrodes are partially exposed as lands, said conductive protrusion includes a fixedly bonding member, said conductive protrusion is fixedly bonded to each of said lands by the fixedly bonding member, at least three of said lands are larger in area than the other lands, the electronic component can stand alone while the conductive protrusion contacts with a flat if the conductive protrusion is fixedly bonded only to each of the larger-area lands, and the conductive protrusions are all formed by fixedly bonding conductive balls substantially equal in size to entire surfaces of the respective lands.

2. The electronic component according to claim 1, wherein
each of the larger-area lands is located at a position proximate to an external end of the substrate.

3. The electronic component according to claim 1, wherein
the conductive balls are fixedly bonded to the entire surfaces of the respective lands by the fixedly bonding member having an amount proportional to an area of each of the lands.

4. The electronic component according to claim 1, wherein
a maximum cross-sectional area of the conductive protrusion fixedly bonded to each of said larger-area lands along a substrate surface is larger than a maximum cross-sectional area of the conductive protrusion fixedly bonded to each of the other lands along the substrate surface.

5. The electronic component according to claim 1, wherein
a region in which each of the electrodes extending from each larger-area land is connected to the restive element or the dielectric while superimposing each other is present while avoiding a line that connects a shortest path between a center of each larger-area land, and the electrode that is arranged on the other end and that pairs with said electrode.

6. The electronic component according to claim 1, wherein
a size of the substrate in a direction of a longer side of the substrate is larger than a size of the substrate in a direction of a shorter side of the substrate on each larger-area land.

7. The electronic component according to claim 1, wherein
each larger-area land is present in each of four corners of a tetragonal substrate.

8. The electronic component according to claim 1, wherein
each larger-area land is present at a position proximate to each of both external ends of the tetragonal substrate in the direction of the shorter side of the substrate.

9. The electronic component according to claim 1, wherein
each larger-area land is one of a tetragon, an ellipse, and a tetragon having four round corners.

10. The electronic component according to claim 1, wherein
a size of each larger-area land in the direction of the longer side of the substrate is larger than a size of each larger-area land in the direction of the shorter side of the substrate.

11. The electronic component according to claim 1, wherein
the conductive protrusion substantially does not contain lead.

12. The electronic component according to claim 11, wherein
the conductive protrusion mainly consists of copper.

13. The electronic component according to claim 1, wherein
the resistive elements or the dielectrics that constitute the electronic component are substantially equal in shape, and distances between the adjacent resistive elements or the adjacent dielectrics are substantially equal.

14. The electronic component according to claim 1, wherein
each larger-area land consists of Metal Graze® material, and an entire surface of each larger-area land is covered with the fixedly bonding member.
